(19) United States
(12) Patent Application Publication
(10) Pub. No.: US 2012/0104368 A1
(43) Pub. Date: May 3, 2012

(54) DISPLAY APPARATUS

(75) Inventors: Ryuichiro Isobe, Chiba-shi (JP); Toshinori Hasegawa, Yokohama-shi (JP); Yojiro Matsuda, Kawasaki-shi (JP)

(73) Assignee: CANON KABUSHIKI KAISHA, Tokyo (JP)

(21) Appl. No.: 13/274,631

(22) Filed: Oct. 17, 2011

(30) Foreign Application Priority Data
Oct. 27, 2010 (JP) 2010-241207
Aug. 30, 2011 (JP) 2011-187168

(51) Int. Cl. H01L 27/32

(52) U.S. Cl. 257/40; 257/E27.119

(57) ABSTRACT

In a display apparatus in which a plurality of pixel units including a plurality of pixels whose emission colors are different are arranged and white is displayable by the pixel unit, the pixel includes an organic EL device, and lenses are provided in the pixel unit to minimize a difference of currents supplied to the organic EL devices for respective emission colors when white of desired luminance is displayed.

### BACKGROUND OF THE INVENTION

1. Field of the Invention

The present invention relates to a display apparatus including an organic electroluminescence (EL) device.

2. Description of the Related Art

In recent years, research and development of the display apparatus including an organic EL device has been more actively conducted. An organic EL device is composed of an anode, an organic compound layer containing a light emitting layer, and a cathode, holes and electrons are injected into the light emitting layer from the anode and the cathode, respectively, and light is emitted from the light emitting layer by using recombination energy of a hole and an electron.

In a display apparatus including a plurality of organic EL devices emitting mutually different colors such as, for example, red, green, and blue to enable a color display, the organic EL devices of respective colors are caused to emit light to display white. However, the currents (required currents) to be supplied to the organic EL devices of respective colors (red, green, and blue) are different, thus making drive circuits of a pixel circuit, a peripheral circuit, a wire, and the like of respective colors complex.

More specifically, if characteristics of a transistor adjusting the current to be supplied to organic EL devices are fitted to an organic EL device whose required current is large, an organic EL device whose required current is small may have an insufficient resolution, so that a separate circuit is needed to compensate for the insufficient resolution. If a transistor is designed in such a way that the necessary resolution can be secured for an organic EL device whose required current is small, the transistor may be over engineered for an organic EL device whose required current is large.

In contrast, Japanese Patent Application Laid-Open No. 2001-290441 discusses supplying the same amount of current to the organic EL devices of respective colors by adjusting the area of a light emitting region of respective colors.

However, increasing or decreasing the area of a light emitting region in a display apparatus is limited, and according to the method discussed in Japanese Patent Application Laid-Open No. 2001-290441, a difference of currents supplied to organic EL devices of respective colors cannot be adequately handled.

### SUMMARY OF THE INVENTION

The present invention features a display apparatus capable of reducing a difference of currents supplied to organic EL devices of respective colors when white is displayed by using lenses capable of handling a difference of currents between still wider emission colors.

According to an aspect of the present invention, there is provided a display apparatus in which a plurality of pixel units including a plurality of pixels whose emission colors are different are arranged and white is displayable by the pixel unit, wherein the pixel includes an organic EL device, and wherein lenses are provided in the pixel unit to minimize a difference of currents supplied to the organic EL devices for respective emission colors when white of desired luminance is displayed.

According to an exemplary embodiment of the present invention, a display apparatus in which a difference of currents supplied to organic EL devices of respective colors when white is displayed is reduced can be obtained by using lenses.

Further features and aspects of the present invention will become apparent from the following detailed description of exemplary embodiments with reference to the attached drawings.

### BRIEF DESCRIPTION OF THE DRAWINGS

The accompanying drawings, which are incorporated in and constitute a part of the specification, illustrate exemplary embodiments, features, and aspects of the invention and, together with the description, serve to explain the principles of the invention.

FIGS. 1A and 1B are a perspective schematic diagram and a partial sectional schematic diagram illustrating an example of a display apparatus according to a first exemplary embodiment of the present invention.

FIG. 2 is a partial sectional schematic diagram of a display apparatus.

FIG. 3 is a diagram illustrating a correlation between a radiation angle and relative luminance.

FIGS. 4A to 4E are diagrams illustrating a manufacturing process of the display apparatus according to the first exemplary embodiment.

FIG. 5 is a partial sectional schematic diagram illustrating an example of a display apparatus according to a second exemplary embodiment of the present invention.

FIGS. 6A to 6C are diagrams illustrating a manufacturing process of the display apparatus according to the second exemplary embodiment.

### DESCRIPTION OF THE EMBODIMENTS

Various exemplary embodiments, features, and aspects of the invention will be described in detail below with reference to the drawings.

If not specifically illustrated or mentioned herein, widely known or publicly known technology in the art is applied. Each exemplary embodiment described below is merely one exemplary embodiment of the invention and is not limited to such exemplary embodiments. In the present specification, a required current ratio is a ratio of current values of respective colors (for example, red, green, and blue) required when white of desired luminance is displayed and, for example, a ratio of luminances of respective colors/luminous efficiency of respective colors when white of desired luminance is displayed.

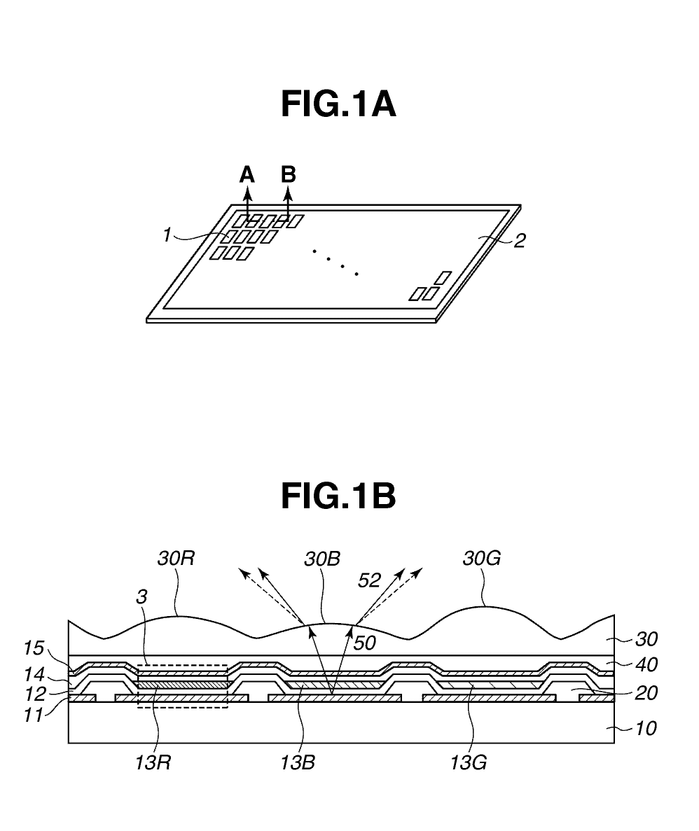

FIG. 1A is a perspective schematic diagram illustrating a display apparatus according to a first exemplary embodiment of the present invention. The display apparatus in the present exemplary embodiment has a plurality of pixels 1 each including an organic EL device. The plurality of pixels 1 is arranged like a matrix to form a display region 2. The pixel means a region corresponding to a light emitting region of one light-emitting device. In the display apparatus according to the present exemplary embodiment, the light-emitting device is an organic EL device and the organic EL device of one color is arranged in each of the pixels 1. Emission colors of the organic EL devices include red, green, and blue and, in addition, may include yellow and cyan. Also in the display apparatus according to the present exemplary embodiment, a plurality of pixel units composed of a plurality of pixels of different emission colors (for example, a pixel emitting red, a pixel emitting green, and a pixel emitting blue) is arranged. The pixel unit is the minimum unit enabling emission of a desired color by color mixing of each pixel.

FIG. 1B is a partial sectional schematic diagram taken along line A-B in FIG. 1A. The pixel 1 has an organic EL device 3 including a first electrode (anode) 11, a hole transport layer 12, light emitting layers 13R, 13G, 13B, an electron transport layer 14, and a second electrode (cathode) 15 on a substrate 10. In the present exemplary embodiment, the light emitting layer 13R is a light emitting layer emitting red, the light emitting layer 13G is a light emitting layer emitting green, and the light emitting layer 13B is a light emitting layer emitting blue. The light emitting layers 13R, 13G, 13B are pattern-formed corresponding to the pixels (organic EL devices 3) emitting red, green, and blue, respectively. The first electrode 11 is also formed by being separated from the first electrode 11 of the adjacent pixel (organic EL device 3). The hole transport layer 12, the electron transport layer 14, and the second electrode 15 maybe formed in common with the adjacent pixel or pattern-formed for each pixel. An insulating layer 20 is provided between pixels (more specifically, the first electrodes 11) to prevent a short-circuit between the first electrode 11 and the second electrode 15 due to foreign matter.

Further, a lens member 30 is provided in the display apparatus according to the present exemplary embodiment. A protective layer 40 to protect the organic EL device 3 from moisture and oxygen is provided between the lens member 30 and each of the organic EL devices 3. The lens member 30 is configured to have convex portions on the surface thereof, and convex lenses 30R, 30G, and 30B are arranged in positions corresponding to each pixel. The convex lenses 30R, 30G, and 30B are adjusted to have mutually different curvature radii. With this configuration, condensing characteristics of the lens can be changed for each pixel. In the present exemplary embodiment, a difference of currents supplied to organic EL devices for respective emission colors of the pixels when white of desired luminance is displayed is minimized by adjusting condensing characteristics of the lens for each color. A concrete description thereof is provided below. “Condensing characteristics” are characteristics in which the angle of emergence of emerging light becomes smaller than the angle of incidence of light incident on an interface. Condensing characteristics can also be controlled by the region occupied by a lens of the pixel region, radius of curvature (or curvature) of a lens, distance from the light emitting layer (organic EL device) to a lens, and refractive index of the material of a lens.

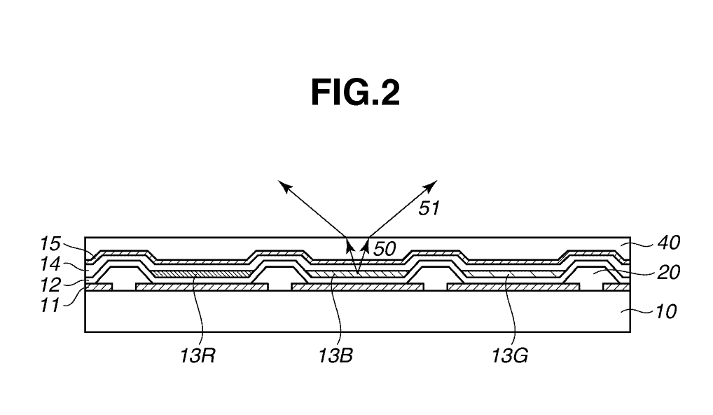

First, as illustrated in FIG. 2, a case when no lens is formed in a pixel is considered. Light 50 emerging obliquely from an organic EL device emerges as more oblique light 51 when emerging from the protective layer 40. When a convex lens (for example, the convex lens 30B) is formed in a pixel as illustrated in FIG. 1B, by contrast, the light 50 emerging after passing through the convex lens 30B emerges as light 52, compared with a case when there is no lens (broken line), more inclined toward the vertical direction of the substrate 10 (front direction of the display apparatus). Therefore, compared with a case when there is no lens, a case when there is a lens has a function to condense light. Thus, luminance when observed from the front direction becomes higher as a display apparatus, so that efficiency of using light in the front direction can be increased.

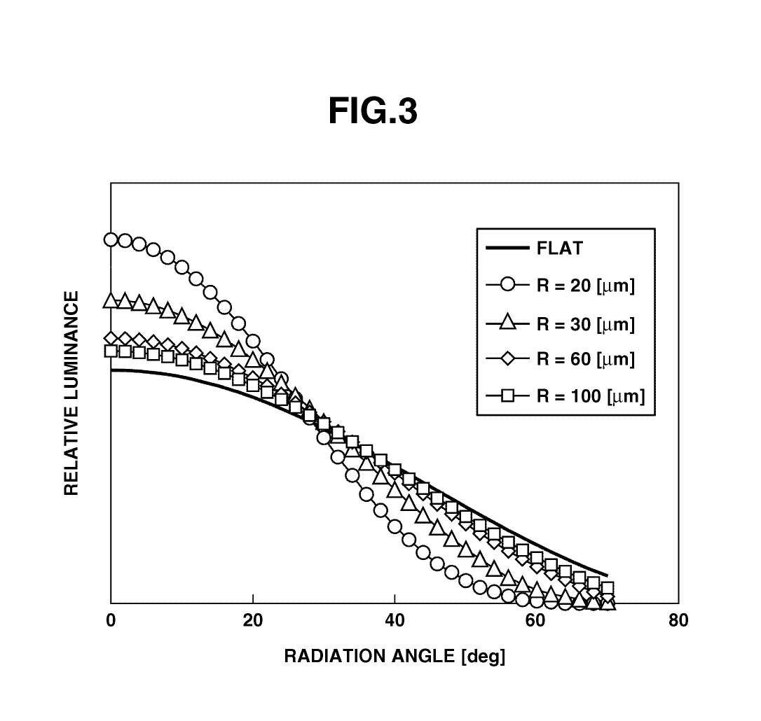

Next, the curvature of a convex lens and luminance in the front direction will be described. FIG. 3 is a diagram illustrating a correlation between the radiation angle and relative luminance when curvature radii R of lenses are different. In FIG. 3, “Flat” denotes a case when no lens is formed. Four kinds of convex lenses with the curvature radii R of 20 μm, 30 μm, 60 μm, and 100 μm are used for measurement. In the configuration of each radius of curvature, the pitch of the pixel is 31.5 μm, the maximum width of the convex lens is 31.5 μm, and the width of the pixel is 16.5 μm. The second electrode 15 is constituted of a mixture of indium oxide and zinc oxide and has a refractive index of 1.9 and a film thickness of 0.05 μm. The protective layer 40 is constituted of silicon nitride and has a refractive index of 1.83 and a film thickness of 0.18 μm. The lens member 30 is constituted of epoxy resin and has a refractive index of 1.54 and a minimum film thickness of 10 μm. The relative luminance means relative luminance when luminance (front luminance) at a radiation angle of 0 degrees (front direction) in each configuration is set as 1.

As illustrated in FIG. 3, relative luminance is higher when the radiation angle is 30 degrees or less, particularly, when a lens is formed in the front direction than when no lens is formed. Further, even if a convex lens is formed, it is evident that relative luminance increases with a decreasing radius of curvature of the convex lens. This indicates that a convex lens with a smaller radius of curvature has greater condensing characteristics of a convex lens than a convex lens with a larger radius of curvature. That is, condensing characteristics increase in the order of a configuration in which no lens is provided, a configuration in which a convex lens with a large radius of curvature is provided, and a configuration in which a convex lens with a small radius of curvature is provided. Therefore, a pixel including a lens with increasing condensing characteristics has higher relative luminance in the front direction of a display apparatus.

Generally, a display apparatus is observed frequently from the front direction and a display apparatus with high front luminance is desired. If, as described above, front luminance is made higher by a lens with condensing characteristics than when no lens is provided, the amount of current supplied to the organic EL device can be made smaller than when no lens is provided to obtain desired front luminance. Thus, the amount of current supplied can be made smaller when a lens with condensing characteristics is provided. When the same luminance is displayed, the amount of current supplied to an organic EL device provided with a lens having great condensing characteristics can be made smaller than the amount of current supplied to an organic EL device provided with a lens having small condensing characteristics.

On the other hand, the organic EL device has different materials and thickness of the light emitting layer and other organic compound layers for each emission color and so has different luminous efficiency for each emission color. The current supplied to the organic EL device when white is displayed is determined by a difference of luminous efficiency for each emission color and the ratio of luminance of respective colors when white is displayed, so that the current (required current) supplied to the organic EL device for each emission color is different. Thus, the drive circuit becomes complex.

Thus, in the display apparatus according to the present exemplary embodiment, a lens whose condensing characteristics are adjusted is provided in each pixel unit according to the color emitted by each pixel so that a difference of currents (or the required current ratio) between organic EL devices emitting different colors is minimized. For example, a case when a pixel unit composed of a pixel emitting red to a display apparatus, a pixel emitting green thereto, and a pixel emitting green thereto is mounted thereon to display white by mixing the three colors is assumed. Chromaticity coordinates of respective colors in the front are assumed to be red (0.67, 0.33), green (0.21, 0.71), and blue (0.14, 0.08) in CIExy. Also, luminous efficiency of respective colors is assumed to be red 12 cd/A, green 10 cd/A, and blue 5 cd/A. To display white of chromaticity coordinates of (0.31, 0.33), the luminance ratio of red, green, and blue becomes about 3:6:1. The required current ratio of red, green, and blue is represented by the ratio (required current ratio) of luminance of respective colors/luminous efficiency of respective colors when white of desired luminance is displayed obtained by dividing luminance (or luminance ratio) of respective colors when white of desired luminance is displayed by luminous efficiency (or luminous efficiency ratio) of respective colors. That is, in the above case, the required current ratio of red, green, and blue becomes about 5:12:4. In the present exemplary embodiment, the lens is provided in such away that the front luminance ratio of red, green, and blue becomes 5:12:4 by supplying the same current to each organic EL device of red, green, and blue. Accordingly, the ratio of currents flowing to the organic EL devices of red, green, and blue can be adjusted to 1:1:1, so that the configuration of the drive circuit can be optimized while preventing the configuration from becoming complex.

Luminance of respective colors/luminous efficiency of respective colors when white of desired luminance is displayed represents an amount proportional to the current (required current) supplied to each organic EL device when no lens is provided for the white display of any level of luminance. In the present exemplary embodiment, condensing characteristics of the lens provided in each pixel are adjusted according to the ratio of respective colors of an amount proportional to the required current, that is, the required current ratio of respective colors. The ratio of luminance ratio of respective colors/luminous efficiency of respective colors when white of desired luminance is displayed, the ratio of luminance of respective colors/luminous efficiency ratio of respective colors when white of desired luminance is displayed, or the ratio of luminance ratio of respective colors/luminous efficiency ratio of respective colors when white of desired luminance is displayed may be used as representing the required current ratio.

As a more concrete configuration in the present exemplary embodiment, a lens with greater condensing characteristics is provided in a pixel having an organic EL device with a larger required current ratio and a lens with smaller condensing characteristics is provided in a pixel having an organic EL device with a smaller required current ratio. When condensing characteristics are controlled by the radius of curvature of a convex lens, a convex lens with a smaller radius of curvature is provided in a pixel having an organic EL device with a larger required current ratio and a convex lens with a larger radius of curvature is provided in a pixel having an organic EL device with a smaller required current ratio.

In a display apparatus including an organic EL device emitting red (hereinafter, called an R device), an organic EL device emitting green (hereinafter, called a G device), or an organic EL device emitting blue (hereinafter, called a B device) in each pixel, for example, a case when the required current ratio increases in the order of the B device, R device, and G device will be considered (required current for the B device<required current for the R device<required current for the G device). In this case, condensing characteristics of the lens to be provided may be increased in the order of the B device, R device, and G device (condensing characteristics for the B device<condensing characteristics for the R device<condensing characteristics for the G device). With this configuration, a pixel having the G device in which a lens with greater condensing characteristics is provided has higher front luminance so that the current supplied for the white display can be reduced. Thus, the current supplied for the white display can be brought closer to the current supplied to the B device with a smaller required current ratio. Similarly, for a pixel having the R device, the current supplied for the white display can be brought closer to the current supplied to the B device. That is, currents supplied to the G device and R device can be brought closer to the current supplied to the B device so that a difference of the required current ratio of the B device, R device, and G device can be made smaller by the lens.

Condensing characteristics need not necessarily be changed for each color and may only be changed when necessary. If, for example, the required current ratio of the B device, R device, and G device is mutually different, for example, the same condensing characteristics may be adopted for the B device and G device so that only condensing characteristics of the lens provided in the R device are changed.

Generally, an organic EL device emitting green has higher luminance when white is displayed than that of organic EL devices emitting other colors. Thus, it is desirable to maximize condensing characteristics of a lens provided in the G device or to provide a lens with condensing characteristics only in the G device.

Condensing characteristics can also be adjusted with a configuration in which a convex lens is provided and a configuration in which no convex lens is provided. That is, a convex lens is provided in a pixel having an organic EL device with a larger required current ratio and no convex lens is provided in a pixel having an organic EL device with a smaller required current ratio.

The substrate 10 is an insulating substrate on which switching devices (not illustrated) such as a thin film transistor (TFT) and metal insulator metal (MIM) are formed and is formed of glass, plastic, or the like. The substrate 10 may include an interlayer dielectric film in which a contact hole to electrically connect a switching device and the first electrode 11 is formed. Further, the substrate 10 may include a planarization film to planarize irregularities of switching devices.

A metal film made of a single metal element such as Al, Cr, and Ag or an alloy thereof can be used for the first electrode 11. Further, a configuration in which a transparent oxide conductive layer such as a compound layer of indium oxide and tin oxide and a compound layer of indium oxide and zinc oxide is stacked on a metal layer can be adopted. The thickness of the first electrode 11 can be 50 nm or more and 200 nm or less. Transparent means having a light transmittance of 40% or more in a visible light region (wavelength: 400 nm to 780 nm).

The hole transport layer 12 is composed of a single layer or a plurality of layers of organic compounds having hole injectability and hole transportability. On the other hand, the electron transport layer 14 is composed of a single layer or a plurality of layers of organic compounds having electron injectability and electron transportability. An electron blocking layer may be provided if necessary as the hole transport layer 12 to suppress movement of electrons from the light emitting layer to the anode side. Also, a hole blocking layer maybe provided as the electron transport layer 14. Also, an exciton blocking layer to suppress diffusion of excitons generated in the light emitting layer may be provided as the hole transport layer 12 and the electron transport layer 14.

There is no limit to materials used as the light emitting layer 13R emitting red, the light emitting layer 13G emitting green, and the light emitting layer 13B emitting blue and any publicly known material may be used. For example, a single layer of a material having both luminous properties and carrier transportability or a mixing layer of a light emitting material such as a fluorescent material and phosphorescent material and a host material with carrier transportability can be applied.

Publicly known materials can be used for each of the light emitting layers 13R, 13G, 13B, the hole transport layer 12, and the electron transport layer 14 and also publicly known methods for forming a film such as deposition and transfer can be used as the method for forming a film. It is desirable to form each layer to an optimum thickness to improve luminous efficiency of the organic EL device of each color and the desirable thickness of each layer is 5 nm or more and 100 nm or less.

A metal film made of a single metal element such as Al, Cr, and Ag or an alloy thereof can be used for the second electrode 15. Particularly, Ag is useful for the second electrode 15 because a metal thin film containing Ag has low absorptance and also low specific resistance. The thickness of the second electrode 15 can be 5 nm or more and 30 nm or less. The second electrode 15 may have a configuration in which the above-described metal thin film and the transparent oxide conductive layer such as a compound layer of indium oxide and tin oxide and a compound layer of indium oxide and zinc oxide are stacked or a configuration of only the transparent oxide conductive layer.

Publicly known materials and methods of forming a film can be used for the protective layer 40. As an example, the method of forming silicon nitride and silicon oxynitride by a chemical vapor deposition (CVD) apparatus can be cited. The protective layer 40 can have a thickness of 0.5 μm to 10 μm to obtain protective properties.

Thermosetting resins, thermoplastic resins, or photo-setting resins containing less moisture may be used for the lens member 30. The lens member 30 can have a thickness of 10 μm to 100 μm. When a thermosetting resin or photo-setting resin is used, the spin coating method or dispense method may be used as the method of forming a film. Also, the method of appending a film of thermoplastic resin whose thickness is 10 μm to 100 μm onto the protective layer 40 in a vacuum may be used. An epoxy resin or butyl resin may suitably be used as a concrete resin material.

Inorganic matter such as silicon nitride and silicon oxide may be used as a material of the lens member 30. In such a case, a silicon nitride layer or silicon oxide layer is first deposited to about 20 μm by the CVD method and then a lens-shaped structure is created with resin thereon. A lens shape can be transferred to the silicon nitride layer or silicon oxide layer by dry etching thereof.

The following methods can be cited as methods of manufacturing the convex lenses 30R, 30G, and 30B:

(1) Method of preparing a lens mold and pressing the mold against a resin layer to form a lens shape;

(2) Method of treating the resin layer patterned by photolithography or the like thermally and deforming the resin layer to a lens shape by the reflow;

(3) Method of forming a lens by exposing a photo-setting resin layer formed to a uniform thickness to light having a distribution in an in-plane direction and developing the resin layer;

(4) Method of processing the surface of a resin material formed to a uniform thickness by an ion beam, electron beam, or laser to a lens shape;

(5) Method of forming a lens self-aligningly by dropping an appropriate amount of resin to each pixel; and

(6) Method of forming a lens by preparing a resin sheet on which a lens is formed in advance separately from a substrate on which organic EL devices are formed and then aligning and appending both.

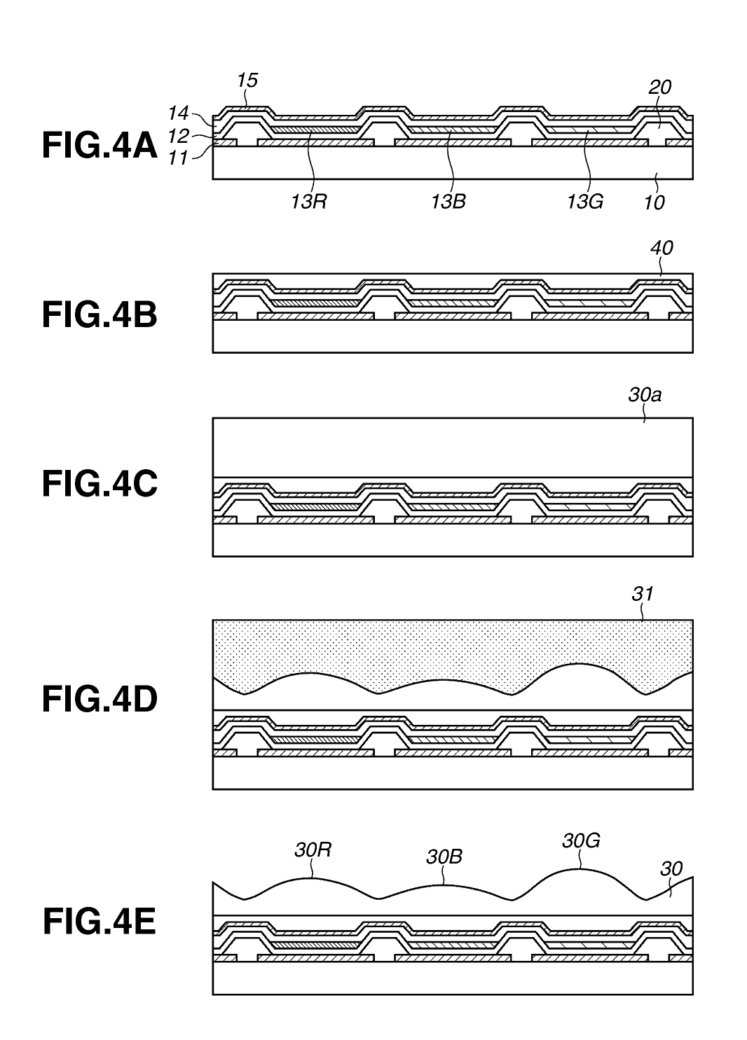

A case when the method of (1) described above is used for the manufacture of a display apparatus in the present exemplary embodiment will be described using FIGS. 4A to 4E. Publicly known methods are used as the methods to form the first electrode 11 to the second electrode 15 on the substrate 10 and thus omitted here.

First, as illustrated in FIG. 4A, a plurality of top-emission type organic EL devices is formed on the substrate 10. Next, as illustrated in FIG. 4B, the protective layer 40 is formed in an entire display region as if to cover the organic EL devices. The protective layer 40 is used to protect the organic EL devices from moisture and oxygen in the air and also from moisture contained in a resin material 30a formed later and has also a function of planarization to form a lens thereon with precision.

Next, as illustrated in FIG. 4C, the resin material 30a to be the source of the lens member 30 is formed on the protective layer 40. Then, as illustrated in FIG. 4D, a mold 31 to mold the convex lenses 30R, 30G, and 30B is prepared and is pressed against the resin material 30a so that air bubbles are not mixed into the resin material 30a. A recess is formed on the surface of the mold 31 in contact with the resin material 30a corresponding to each pixel and the radius of curvature of each recess is adjusted according to condensing characteristics of the convex lens provided in each pixel.

The mold 31 may be formed of a common metal, but if a photo-setting resin is used for the resin material 30a, it is necessary to allow light to pass through and thus, the mold 31 can be formed of a quartz substrate. Moreover, a film of a fluoresin or the like maybe formed on the surface of the mold 31 to increase peeling properties of the mold 31 from the lens member 30.

If a thermosetting resin is used for the resin material 30a, the resin material 30a is set by heating up to 80° C. in a state in which the apex of a recess in the mold 31 approximately matches the center of a corresponding pixel. The heatresistant temperature of organic compounds constituting a common organic EL device is about 100° C. and thus, the setting temperature of about 80° C., which is lower than 100° C., is useful.

Next, as illustrated in FIG. 4E, the mold 31 is removed from the set lens member 30. Accordingly, the convex lenses 30R, 30G, and 30B are formed corresponding to each pixel on the surface of the lens member 30.

If the convex lenses 30R, 30G, and 30B are formed of a resin, it is desirable to form a second protective layer (not illustrated) made of inorganic matter on the lens so that the lens shape should not be damaged. The second protective layer may be formed by using the same material and method as those of the protective layer 40.

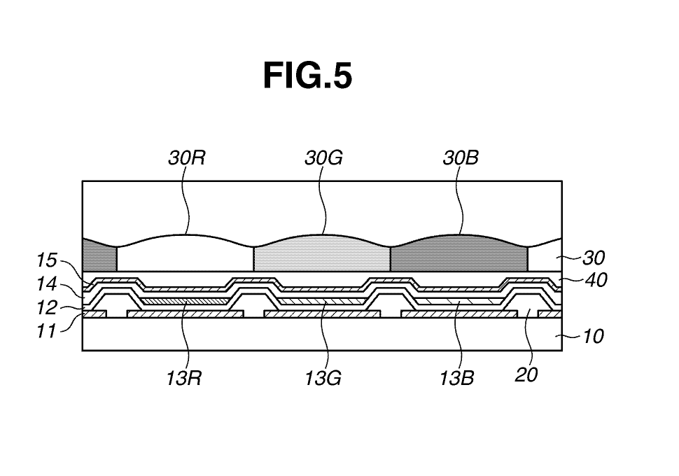

FIG. 5 is a partial sectional schematic diagram of a display apparatus according to a second exemplary embodiment of the present invention. The first exemplary embodiment relates to a display apparatus that minimizes a difference of currents supplied to organic EL devices when white is displayed by having different curvature radii of lenses for each color to control condensing characteristics. In contrast, the present exemplary embodiment relates to a display apparatus that minimizes a difference of currents supplied to organic EL devices when white is displayed by having different refractive indices of lenses for each color to control condensing characteristics.

Generally, with an increasing refractive index of a convex lens, condensing characteristics of the lens increase. Thus, a convex lens with a large refractive index is provided in a pixel having an organic EL device with a larger required current ratio to increase condensing characteristics and a convex lens with a small refractive index is provided in a pixel having an organic EL device with a smaller required current ratio.

More specifically, a case when the required current ratio increases in the order of the B device, R device, and G device will be considered (required current for the B device<required current for the R device<required current for the G device). In this case, as illustrated in FIG. 5, the refractive index of the convex lens is increased in the order of the B device, R device, and G device (refractive index of the convex lens in the B device<refractive index of the convex lens in the R device<refractive index of the convex lens in the G device). With this configuration, a pixel having the G device in which a lens with a large refractive index and greater condensing characteristics is provided has higher front luminance so that the current supplied for the white display can be reduced. Thus, the current supplied for the white display can be brought closer to the current supplied to the B device with a smaller required current ratio. Similarly, for a pixel having the R device, the current supplied for the white display can be brought closer to the current supplied to the B device. That is, currents supplied to the G device and R device can be brought closer to the current supplied to the B device so that a difference of the required current ratio of the B device, R device, and G device can be made smaller by the lens.

A display apparatus in the present exemplary embodiment can also be manufactured by the same method as that in the first exemplary embodiment. In the present exemplary embodiment, the radius of curvature of the convex lens of each pixel may be the same, but may also be different. Particularly, like in the first exemplary embodiment, it is desirable to provide a convex lens with a small radius of curvature in a pixel having an organic EL device with a larger required current ratio and a convex lens with a large radius of curvature in a pixel having an organic EL device with a smaller required current ratio.

The method of adjusting the refractive index by a resin forming a lens is known as a method of controlling the refractive index. Further, the method of having an inorganic material in a resin forming a lens and adjusting the refractive index of the inorganic material or the content thereof in the resin is known. Organic materials include, for example, titanium oxide (2.90), ITO (2.12), mercury sulfide (2.81), cobalt green (1.97), and cobalt blue (1.74).

As described above, condensing characteristics can be controlled by a method that is different from the methods in the first and second exemplary embodiments. For example, when condensing characteristics are controlled by a region occupied by a lens of the pixel region, effects of the present invention are gained if the following configuration is adopted. That is, the region occupied by a lens is increased for a pixel having an organic EL device with a smaller required current ratio and the region occupied by a lens is decreased for a pixel having an organic EL device with a larger required current ratio. With this configuration, the ratio of light passing through the lens of the light emerging from a light emitting region (pixel) can be adjusted so that condensing characteristics of the whole pixel can be controlled.

The above configuration is a configuration in which a lens is provided to fit to the current of the color with a smaller required current ratio, but chromaticity shifts of white can also be reduced even by a configuration in which a lens is provided to fit to the current of the color with a larger required current ratio. More specifically, the following configuration can be cited.

That is, condensing characteristics can be adjusted by mixing a configuration in which a convex lens is provided and a configuration in which a concave lens is provided. A concave lens has smaller condensing characteristics and larger divergent characteristics than a configuration in which a convex lens is provided and also smaller than a configuration in which no lens is provided. By using the characteristics, a concave lens may be provided in a pixel having an organic EL device with a smaller required current ratio and a convex lens may be provided in a pixel having an organic EL device with a larger required current ratio.

By using the fact that a concave lens has smaller condensing characteristics (larger condensing characteristics) with a decreasing radius of curvature, condensing characteristics of pixel can be controlled only by concave lenses. That is, a concave lens with a small radius of curvature is provided in a pixel having an organic EL device with a smaller required current ratio and a concave lens with a large radius of curvature is provided in a pixel having an organic EL device with a larger required current ratio. Even with this configuration, a difference of currents of organic EL devices of respective colors can be made smaller.

Display apparatuses in the present exemplary embodiment include a TV set, personal computer, imaging apparatus, display unit of a mobile phone, and mobile game machine. In addition, the display apparatuses include a mobile music playback apparatus, mobile information terminal (PDA), car navigation system, and the like.

### EXAMPLE 1

In Example 1, an example in which a difference of currents supplied to organic EL devices when white is displayed is minimized by using lenses having different curvature radii will be described using FIGS. 4A to 4E.

First, a low-temperature polysilicon TFT is formed on a glass substrate and then, an interlayer dielectric film made of silicon nitride and a planarization film made of an acryl resin are formed thereon in this order to create the substrate 10 illustrated in FIG. 4A. An ITO film/AlNd film is formed on the substrate 10 by a sputtering process to a thickness of 38 nm/100 nm. Subsequently, the ITO film/AlNd film is patterned for each pixel to form the first electrode 11.

An acryl resin is formed on the first electrode 11 by spin coating and the acryl resin is patterned by lithography so that an opening (this opening corresponds to a pixel) is formed in a portion where the first electrode 11 is formed to form the insulating layer 20. The pitch of each pixel is set to 30 μm and the size of an exposure portion of the first electrode 11 by the opening is set to 10 μm. Then, the product is ultrasonically cleaned by isopropyl alcohol (IPA) and then dried after cleaning by boiling. Further, the product is cleaned by UV/ozone and the following organic compound films are formed by vacuum evaporation. The degree of vacuum and the deposition rate of each organic compound layer during film formation are 1×10⁻⁴ to 3.0×10⁻⁴ Pa and 0.2 to 0.5 nm/sec, respectively.

First, a compound 1 of the following structural formula is formed to a thickness of 87 nm in common on the first electrode 11 in the entire display region as the hole transport layer 12.

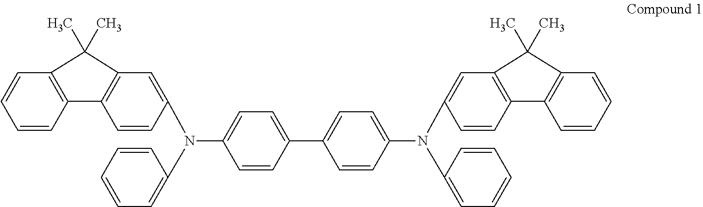

Next, CBP and Ir (piq)₃ as the light emitting layer 13R of red are formed by co-deposition in a portion to be a pixel emitting red by using a deposition mask so that the ratio of weight becomes 91:9 and the thickness thereof becomes 30 nm. Then, Alq₃ and coumarin 6 as the light emitting layer 13G of green are formed by co-deposition in a portion to be a pixel emitting green by using the deposition mask so that the ratio of weight becomes 99:1 and the thickness thereof becomes 40 nm. Then, BAlq and perylene as the light emitting layer 13B of blue are formed by co-deposition in a portion to be a pixel emitting blue by using the deposition mask so that the ratio of weight becomes 97:3 and the thickness thereof becomes 25 nm.

Next, Bphen as the common electron transport layer 14 is formed to a thickness of 10 nm in the entire display region. Further, Bphen and Cs₂CO₃ as a common electron injection layer (part of the electron transport layer 14) are formed by co-deposition (ratio of weight: 90:10) thereon to a thickness of 40 nm.

Next, the above product is moved to a sputtering device without breaking the vacuum and then, Ag and ITO are sequentially formed to a thickness of 10 nm and 50 nm respectively as the second electrode 15.

Next, as illustrated in FIG. 4B, the protective film 40 made of silicon nitride is formed by the plasma chemical vapor deposition (CVD) method using the SiH₄ gas, N₂ gas, and H₂ gas.

Then, as illustrated in FIG. 4C, a thermosetting epoxy resin material whose viscosity is 3000 mPa·s is applied as the resin material 30a by using a dispenser (manufactured by Musashi Engineering, product name: SHOT MINI SL) in a nitrogen atmosphere at an exposure temperature of 60° C.

Before the resin material 30a is thermally cured, as illustrated in FIG. 4D, the mold 31 which is separately prepared to mold the convex lenses 30R, 30G, and 30B is pressed against the surface of the resin material 30a. The mold 31 is pressed after positioning by aligning an alignment mark formed on the mold 31 and an alignment mark formed on the substrate 10. As a result, the convex lenses 30R, 30G, and 30B are formed by being aligned with the pixel. The mold 31 has recesses formed in the same pitch as the pixel pitch and the surface of the mold 31 is coated with a fluorine base resin as a mold releasing agent. The curvature radii of recesses corresponding to pixels of red, green, and blue of the mold 31 are 27.2 μm, 17.5 μm, and 28.6 μm, respectively.

In consideration of the environment of a clean room and process units, the minimum thickness (thickness in the thinnest portion) of the lens member 30 is set to 10 μm to include the purpose of planarizing the resin material 30a even if foreign matter is present.

Next, while the mold 31 is being pressed against the resin material 30a, the mold 31 is heated to 100° C. in a vacuum environment for 15 min to cure the resin material 30a to form the lens member 30. Then, the mold 31 is removed from the lens member 30 to form, as illustrated in FIG. 4E, the convex lenses 30R, 30G, and 30B. The curvature radii of the convex lenses 30R, 30G, and 30B are 27.2 μm, 17.5 μm, and 28.6 μm, respectively.

Further, a protective film (not illustrated) made of silicon nitride is formed by the plasma CVD method using the SiH₄ gas, N₂ gas, and H₂ gas. The thickness of the protective film is 1 μm and is formed to cover the entire display region.

Characteristics of a display apparatus in the present example manufactured as described above are evaluated and results thereof are summarized in Table 1. The luminous efficiency of a single device in Table 1 is a result of evaluation of characteristics of an organic EL device of respective colors without a lens in the pixel. The required current ratio when white is displayed shows the ratio of currents of respective colors required when white (CIExy coordinates (0.310, 0.329)) of desired luminance is displayed.

TABLE 1

| | Red pixel | Green pixel | Blue pixel |
|---|---|---|---|
| Chromaticity | (0.671, | (0.213, | (0.134, |
| | 0.329) | 0.707) | 0.082) |
| Luminous efficiency of | 12.0 cd/A | 10.0 cd/A | 5.0 cd/A |
| single device | | | |
| Luminance ratio when | 0.292 | 0.601 | 0.107 |
| white is displayed | | | |
| Front luminance (when | 2.92 | 7.22 | 2.57 |
| luminance without lens | | | |
| is set to 1) | | | |
| Luminous efficiency of | 35.00 cd/A | 72.20 cd/A | 12.85 cd/A |
| pixel | | | |
| Required current ratio | 1.0 | 1.0 | 1.0 |
| when white is displayed | | | |

It is evident from Table 1 that the required current ratio when white is displayed is made approximately the same for each color in a display apparatus in Example 1 and thus, characteristics of the drive circuit connected to the organic EL device of respective colors can be made uniform. Therefore, excellent display characteristics are exhibited even when the desired gradation of respective colors is displayed.

### Comparative Example 1

The Comparative Example 1 is an example of a display apparatus in which no lens is provided in each pixel and the other configuration is the same as that in Example 1.

TABLE 2

| | Red pixel | Green pixel | Blue pixel |
|---|---|---|---|
| Chromaticity | (0.671, | (0.213, | (0.134, |
| | 0.329) | 0.707) | 0.082) |
| Luminous efficiency of | 12.0 cd/A | 10.0 cd/A | 5.0 cd/A |
| single device | | | |
| Luminance ratio when | 0.292 | 0.601 | 0.107 |
| white is displayed | | | |
| Front luminance (when | 1 | 1 | 1 |
| luminance without lens | | | |
| is set to 1) | | | |
| Luminous efficiency of | 12.0 cd/A | 10.0 cd/A | 5.0 cd/A |
| pixel | | | |
| Required current ratio | 1.1 | 2.8 | 1.0 |
| when white is displayed | | | |

It is evident from Table 2 that a display apparatus in the Comparative Example 1 has a difference of up to about 2.8 times in required current of respective colors. Thus, the drive circuit needs to be fitted to the green pixel with the largest current ratio and thus, gradation shifts are recognized particularly in low-gradation display while blue pixels are displayed.

### Example 2

Example 2 is an example in which a difference of currents supplied to organic EL devices when white is displayed is minimized by adjusting the refractive index of convex lenses.

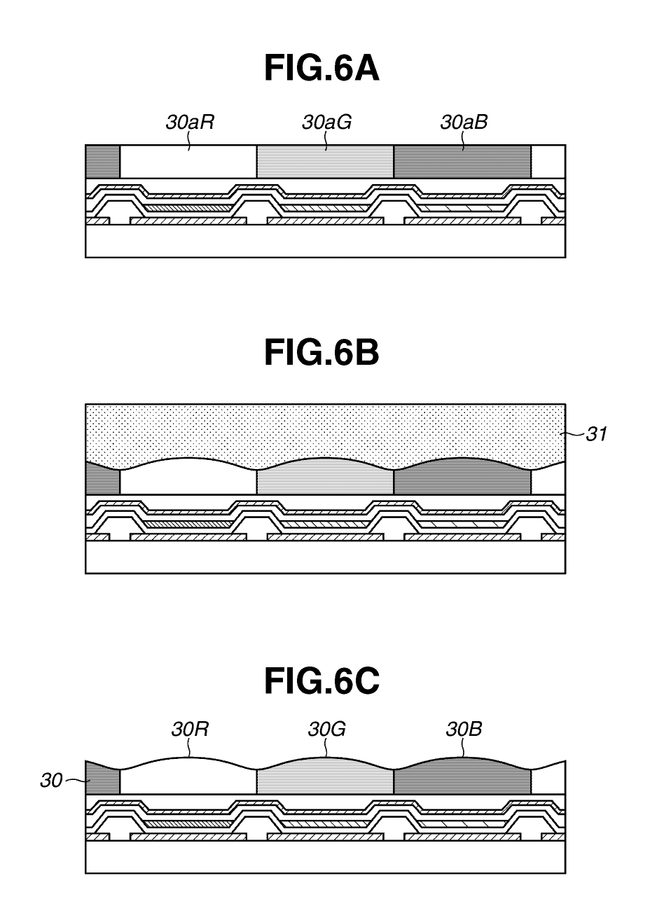

Example 2 is manufactured by the same process as Example 1 except that the application process of a lens member and the surface shape of the mold 31 of a lens are different. Regarding the application process of a lens member, like in Example 1, the protective layer 40 made of silicon nitride is formed and then, as illustrated in FIG. 6A, resin materials 30aR, 30aG, and 30aB in which fine particles of titanium oxide are mixed are applied to respective pixel positions by using a nozzle dispenser. Nozzles in the positions corresponding to pixels of red, green, and blue are filled with resin materials including epoxy resins of different mixing ratios of titanium oxide fine particles to apply the epoxy resins. The ratios of titanium oxide in the epoxy resin with which nozzles in the positions corresponding to pixels of red, green, and blue are filled to the epoxy resin are 10% by weight, 38% by weight, and 6% by weight, respectively.

Next, as illustrated in FIG. 6B, convex lenses are formed by pressing the mold 31 prepared separately against the surface of the resin material 30a. The mold 31 in Example 2 has recesses formed in the same pitch as the pixel pitch and surface shapes of the lenses 30R, 30G, and 30B are the same shape.

Next, while the mold 31 is being pressed against the resin materials 30aR, 30aG, and 30aB, the mold 31 is heated to 100° C. in a vacuum environment for 15 min to cure the resin materials 30aR, 30aG, and 30aB to form the lens member 30. Then, the mold 31 is removed from the lens member 30 to form, as illustrated in FIG. 6C, the convex lenses 30R, 30G, and 30B. The curvature radii of the convex lenses 30R, 30G, and 30B are all 25 μm.

The convex lenses 30R, 30G, and 30B have fine particles of titanium oxide whose refractive index is 2.9 mixed in the epoxy resin whose refractive index is 1.54 and the refractive index of lens is increased in the order of the B device, R device, and G device (refractive index of convex lens of the B device<refractive index of convex lens of the R device<refractive index of convex lens of the G device) by increasing the mixing ratio in the order of the G device, R device, and B device.

Characteristics of a display apparatus manufactured as described above are evaluated and results thereof are summarized in Table 3. The comparative example is the same as that of Example 1.

TABLE 3

| | Red pixel | Green pixel | Blue pixel |
|---|---|---|---|
| Chromaticity | (0.671, | (0.213, | (0.134, |
| | 0.329) | 0.707) | 0.082) |
| Luminous efficiency of | 12.0 cd/A | 10.0 cd/A | 5.0 cd/A |
| single device | | | |
| Luminance ratio when | 0.292 | 0.601 | 0.107 |
| white is displayed | | | |
| Front luminance (when | 2.92 | 7.22 | 2.57 |
| luminance without lens | | | |
| is set to 1) | | | |
| Luminous efficiency of | 35.00 cd/A | 72.20 cd/A | 12.85 cd/A |
| pixel | | | |
| Required current ratio | 1.0 | 1.0 | 1.0 |
| when white is displayed | | | |

It is evident from Table 3 that the required current ratio when white is displayed is made approximately the same for each color in a display apparatus in Example 2 and thus, characteristics of the drive circuit connected to the organic EL device of respective colors can be made uniform. Therefore, excellent display characteristics are exhibited even when the desired gradation of respective colors is displayed.

While the present invention has been described with reference to exemplary embodiments, it is to be understood that the invention is not limited to the disclosed exemplary embodiments. The scope of the following claims is to be accorded the broadest interpretation so as to encompass all modifications, equivalent structures, and functions.

This application claims priority from Japanese Patent Applications No. 2010-241207 filed Oct. 27, 2010 and No. 2011-187168 filed Aug. 30, 2011, which are hereby incorporated by reference herein in their entirety.

What is claimed is:

1. A display apparatus in which a plurality of pixel units, each pixel unit including a plurality of pixels having different emission colors, are arranged and white is displayable by the pixel unit,
wherein the pixel includes an organic electroluminescence (EL) device, and
wherein lenses are provided in the pixel unit to minimize a difference of currents supplied to the organic EL devices for respective emission colors when white of desired luminance is displayed.

2. The display apparatus according to claim 1, wherein a lens with greater condensing characteristics is provided in the pixel including the organic EL device with a larger required current ratio than in the pixel including the organic EL device with a smaller required current ratio.

3. The display apparatus according to claim 1, wherein a lens with condensing characteristics is provided in the pixel including the organic EL device with a larger required current ratio and no lens is provided in the pixel including the organic EL device with a smaller required current ratio.

4. The display apparatus according to claim 2, wherein condensing characteristics are controlled by a radius of curvature of a convex lens or a refractive index of the convex lens.

5. The display apparatus according to claim 4, wherein a convex lens with a smaller radius of curvature is provided in the pixel including the organic EL device with a larger required current ratio than in the pixel including the organic EL device with a smaller required current ratio.

6. The display apparatus according to claim 4, wherein a convex lens with a larger refractive index is provided in the pixel including the organic EL device with a larger required current ratio than in the pixel including the organic EL device with a smaller required current ratio.

7. The display apparatus according to claim 2, wherein the plurality of pixels include a pixel emitting red, green, or blue, and
wherein the organic EL device with a larger required current ratio is the organic EL device emitting blue.
